(19) United States
(12) Patent Application Publication
(10) Pub. No.: US 2009/0303172 A1
(43) Pub. Date: Dec. 10, 2009

(54) ANALOG-TO-DIGITAL CONVERTER, DISPLAY DEVICE INCLUDING THE SAME AND DRIVING METHOD OF THE SAME

(75) Inventors: Seong-Il Park, Seoul (KR); Ho-Suk Maeng, Seoul (KR); Doo-Hyung Woo, Anyang-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/468,370

(22) Filed: May 19, 2009

(30) Foreign Application Priority Data
Jun. 10, 2008 (KR) 10-2008-0054328

(51) Int. Cl. G09G 3/36; H03M 1/12

(52) U.S. Cl. 345/102; 341/137

(57) ABSTRACT

An analog-to-digital (“A/D”) converter includes; a photocurrent integrator which integrates photocurrent and stores the integrated photocurrent in a feedback capacitor in the form of voltage, and a discharger which attenuates the voltage out from the photocurrent integrator in the form of an exponential function.

This application claims priority to Korean Patent Application No. 10-2008-0054328, filed on Jun. 10, 2008, and all the benefits accruing therefrom under 35 U.S.C. §119, the contents of which in its entirety are herein incorporated by reference.

### BACKGROUND OF THE INVENTION

1. Field of the Invention

The present invention relates to an analog-to-digital (“A/D”) converter, a display device including the A/D converter, and a driving method of the display device, and more particularly, to an A/D converter which can be easily implemented and can increase an input dynamic range, a display device including the A/D converter, and a driving method of the display device.

2. Description of the Related Art

A liquid crystal display (“LCD”) includes an LCD panel consisting of a first substrate having pixel electrodes, a second substrate having a common electrode, and a liquid crystal layer having dielectric anisotropy interposed between the first and second substrates. In the LCD, an electric field is created between the pixel electrode and the common electrode, and the intensity of the electric field is adjusted, thereby controlling the orientation of liquid crystal molecules in the liquid crystal layer to control the amount of light passing through the LCD panel, thereby obtaining desired images. The LCD is not a self-emitting device. Hence, it may require a light source to provide back light to the LCD panel.

Methods for adjusting the luminance of back light according to the ambient light that is externally supplied have recently been developed in order to reduce power consumption of a backlight unit. Meanwhile, in order to improve display quality, development is under way for adjusting the luminance of back light according to the image displayed on an LCD panel.

Such LCDs may include a photosensor for detecting the luminance of ambient light or back light. In addition, the LCDs may necessarily include an analog-to-digital converter for converting an output of the photosensor.

### BRIEF SUMMARY OF THE INVENTION

The present invention provides an exemplary embodiment of an analog-to-digital (“A/D”) converter which can be easily implemented and can increase an input dynamic range.

The present invention also provides an exemplary embodiment of a display device including an A/D converter which can be easily implemented and can increase an input dynamic range.

The present invention also provides an exemplary embodiment of a driving method of a display device including an A/D converter which can be easily implemented and can widen an input dynamic range.

The above and other aspects of the present invention will be described in, or will be apparent from, the following description of the exemplary embodiments.

According to one exemplary embodiment of the present invention, an A/D converter includes; a photocurrent integrator which integrates photocurrent and stores the integrated photocurrent in a feedback capacitor in the form of voltage, and a discharger which attenuates the voltage out from the photocurrent integrator in the form of an exponential function.

According to another exemplary embodiment of the present invention, a display device includes; an A/D converter which includes; a photocurrent integrator which integrates photocurrent and stores the integrated photocurrent in a feedback capacitor in the form of voltage, a discharger which attenuates the voltage out from the photocurrent integrator in the form of an exponential function, and a comparator which compares the voltage attenuated by the discharger with a reference voltage, a backlight unit which adjusts luminance of back light according to a time period wherein the attenuated voltage is greater than or equal to the reference voltage, and which outputs the same, and a display panel which receives the back light.

According to still another exemplary embodiment of the present invention, a driving method of a display device includes; integrating photocurrent and storing the integrated photocurrent in a feedback capacitor in the form of voltage, attenuating the voltage out from the photocurrent integrator in the form of an exponential function, and adjusting luminance of back light according to a time period wherein the attenuated voltage is equal to or greater than a reference voltage, and outputting the same.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram illustrating an exemplary embodiment of a display device and a driving method of the same according to the present invention;

FIG. 2 is an equivalent circuit diagram of a single pixel included in an exemplary embodiment of a display panel illustrated in FIG. 1;

FIG. 3 is a detailed block diagram of an exemplary embodiment of an image signal control unit illustrated in FIG. 1;

FIG. 4 is a block diagram of an exemplary embodiment of a light data signal control unit illustrated in FIG. 1;

FIG. 5 is an equivalent circuit diagram illustrating exemplary embodiments of operations of a backlight driver and a light-emitting block illustrated in FIG. 1;

FIG. 6 is an equivalent circuit diagram of an exemplary embodiment of an A/D converter included in an exemplary embodiment of a light measuring unit illustrated in FIG. 1;

FIG. 7 is a timing diagram illustrating signals for driving the exemplary embodiment of a circuit illustrated in FIG. 6;

FIG. 8 is a graph illustrating a change in the length of t1 illustrated in FIG. 7 depending on the magnitude of photocurrent illustrated in FIG. 6;

FIG. 9 is a block diagram illustrating the exemplary embodiment of a light measuring unit illustrated in FIG. 1;

FIG. 10 is an equivalent circuit diagram of an exemplary embodiment of an A/D converter included in the light measuring unit illustrated in FIG. 1 in another exemplary embodiment of a display device according to the present invention; and

FIG. 11 is a graph illustrating conditions for selecting one among first to third feedback capacitors in the exemplary embodiment of a circuit illustrated in FIG. 10.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including”, when used in this specification, specify the presence of stated features, regions, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

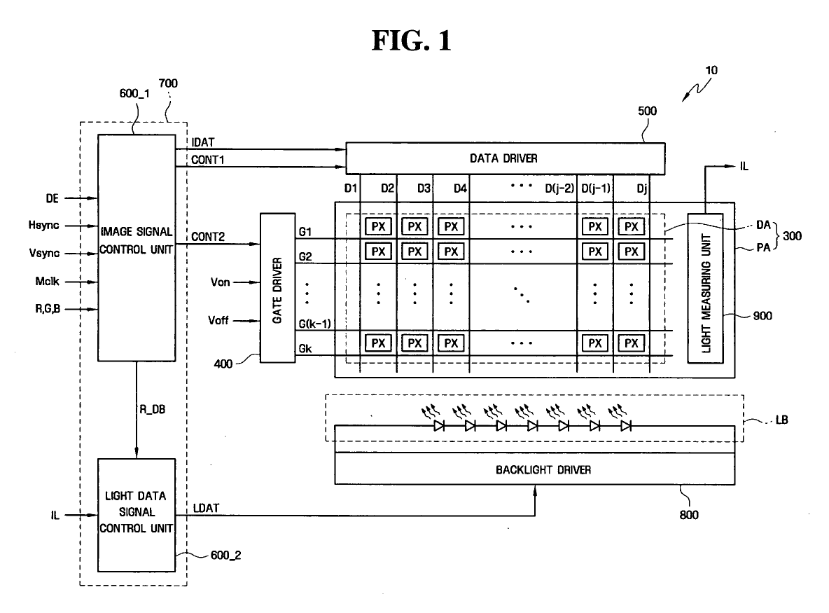

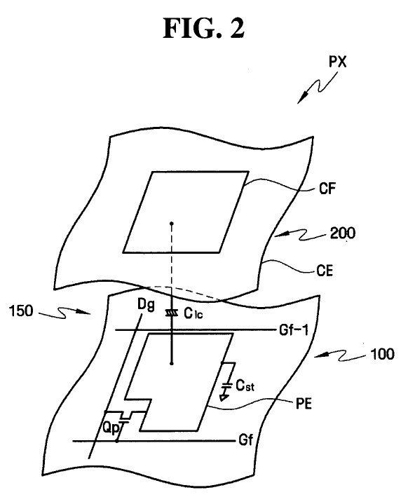

An exemplary embodiment of a display device and a driving method of the same according to the present invention will be described with reference to FIGS. 1 through 9. FIG. 1 is a block diagram illustrating an exemplary embodiment of a display device 10 and a driving method of the same according to the present invention, and FIG. 2 is an equivalent circuit diagram of a single pixel PX included in an exemplary embodiment of a display panel 300 illustrated in FIG. 1.

Referring to FIG. 1, the display device 10 includes a display panel 3 00 having a display area DA on which an image is displayed, and a peripheral PA on which a light measuring unit 900 is mounted, a signal controller 700 consisting of an image signal control unit 600_1 and a light data signal control unit 600_2, a gate driver 400, a data driver 500, a backlight driver 800, and a light-emitting unit LB connected to the backlight driver 800. Here, the image signal control unit 600_1, the light data signal control unit 600_2, the backlight driver 800, and the light-emitting unit LB constitute a backlight unit.

The display panel 300 includes a plurality of gate lines G1-Gk, a plurality of data lines D1-Dj, and a plurality of pixels PX. Each pixel PX is disposed at an intersection area of each of the gate lines G1-Gk and each of the plurality of data lines D1-Dj. Although not shown, the plurality of pixels PX may be divided into red subpixels, green subpixels, and blue subpixels, respectively.

FIG. 2 is an equivalent circuit diagram of a pixel PX. A pixel, e.g., a pixel PX connected to an fth gate line Gf (f=1−k) and a gth data line Dg (g=1−j), includes a switching element Qp connected to the gate line Gf and the data line Dg, and a liquid crystal capacitor C_{1c} and a storage capacitor Cₛₜ connected to the switching element Qp. The liquid crystal capacitor C_{1c} includes two electrodes, for example, a pixel electrode PE disposed on a first substrate 100, a common electrode CE disposed on a second substrate 200, liquid crystal molecules 150 are interposed between the first and second substrates 100 and 200. In one exemplary embodiment, a color filter CF may be formed at a portion of the common electrode CE.

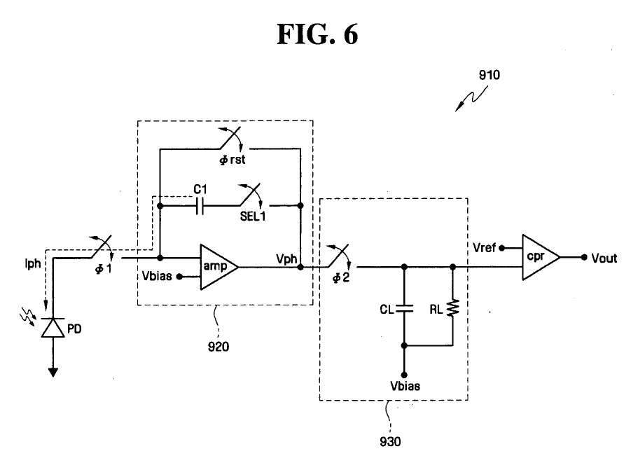

Referring again to FIGS. 1 and 2, the display panel 300 may be divided into a display area DA in which an image is displayed and a peripheral area PA in which an image is not displayed. The display area DA includes the plurality of pixels PX, and each pixel PX displays an image, e.g., transmits light therethrough, in response to an image data voltage supplied from the data driver 500. The peripheral area PA is a non-display area in which an image is not displayed, which is produced because the first substrate 100 is formed wider than the second substrate 200. A light measuring unit 900 may be mounted in the peripheral area PA. The light measuring unit 900 measures the luminance of back light supplied from the light-emitting block LB to output a back light luminance level IL to the signal controller 700. The light measuring unit 900 will later be described in more detail with reference to FIGS. 6 through 9.

The signal controller 700 receives first image signals R, G and B, external control signals Vsync, Hsync, Mclk, and DE, for controlling display of the first image signals R, G, and B, and the back light luminance level IL, and outputs a second image data signal IDAT, a data control signal CONT1, a gate control signal CONT2, and a light data signal LDAT.

In detail, the signal controller 700 may convert the first image signal R, G, B into a second image signal IDAT and output the same. In addition, the signal controller 700 may receive the back light luminance level IL, which is supplied from the light-emitting unit LB, compensate the light data signal LDAT according to the received back light luminance level IL and supply the compensated light data signal LDAT to the backlight driver 800.

In one exemplary embodiment, the signal controller 700 may be functionally divided into an image signal control unit 600_1 and a light data signal control unit 600_2. The image signal control unit 600_1 controls the image displayed on the display panel 300, while the light data signal control unit 600_2 controls the operation of the backlight driver 800. In one exemplary embodiment, the image signal control unit 600_1 and the light data signal control unit 600_2 may be physically separated from each other.

In detail, the image signal control unit 600_1 receives a first image signal R, G, B and outputs a second image signal IDAT corresponding to the received first image signal R, G, B. In one exemplary embodiment, the image signal control unit 600_1 may also receive external control signals Vsync, Hsync, Mclk, and DE, and generate a data control signal CONT1 and a gate control signal CONT2. Examples of the external control signals Vsync, Hsync, Mclk, and DE include a vertical synchronization signal Vsync, a horizontal synchronization signal Hsync, a main clock signal MCLK, and a data enable signal DE. In the present exemplary embodiment, the data control signal CONT1 is used to control the operation of the data driver 500, and the gate control signal CONT2 is used to control the operation of the gate driver 400.

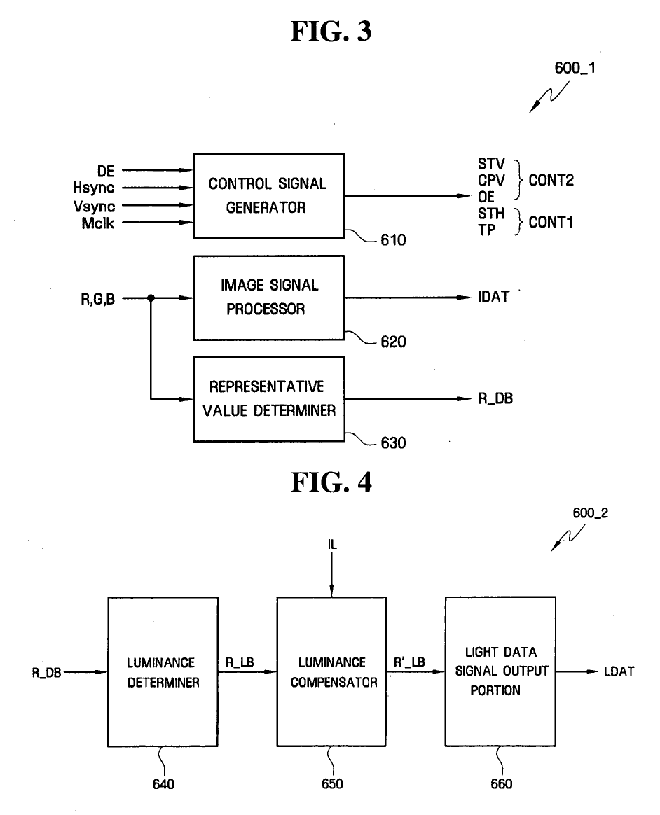

In addition, the image signal control unit 600_1 may receive the first R, G, and B image signal R, G, B, output a representative image signal R_DB, and supply the same to the light data signal control unit 600_2. The image signal control unit 600_1 will be described below in more detail with reference to FIG. 3.

The light data signal control unit 600_2 may receive the representative image signal R_DB and the back light luminance level IL and supply a light data signal LDAT to the backlight driver 800. The light data signal control unit 600_2 will be described below in more detail with reference to FIG. 4.

The gate driver 400, provided with the gate control signal CONT2 from the image signal control unit 600_1, applies a gate signal to the gate lines G1-Gk. Here, the gate signal is composed of a combination of a gate-on voltage Von and a gate-off voltage Voff, which may be generated from a gate on/off voltage generator (not shown). The gate control signal CONT2 for controlling the operation of the gate driver 400 includes a vertical synchronization start signal instructing start of the operation of the gate driver 400, a gate clock signal controlling an output timing of the gate-on signal, an output enable signal that determines a pulse width of the gate-on voltage Von, etc. Although not shown in the drawing, alternative exemplary embodiments include configurations wherein the gate driver 400 may include a plurality of gate driving chips.

The data driver 500 receives the data control signal CONT1 from the image signal control unit 600_1 and applies a voltage corresponding to the second image signal IDAT to the data lines D1-Dj. In one exemplary embodiment, the voltage corresponding to the second image signal IDAT may be a voltage supplied from a gray voltage generator (not shown) according to grayscales of the second image signal IDAT. That is to say, the voltage may be obtained by dividing a driving voltage of the gray voltage generator according to the grayscales of the second image signal IDAT. The data control signal CONT1 includes signals for controlling the operation of the data driver 500. The signals for controlling the operation of the data driver 500 include a horizontal synchronization start signal for starting the operation of the data driver 500, an output enable signal that determining the output of an image data voltage, etc. Although not shown in the drawing, alternative exemplary embodiments include configurations wherein the data driver 500 may include a plurality of data driving chips.

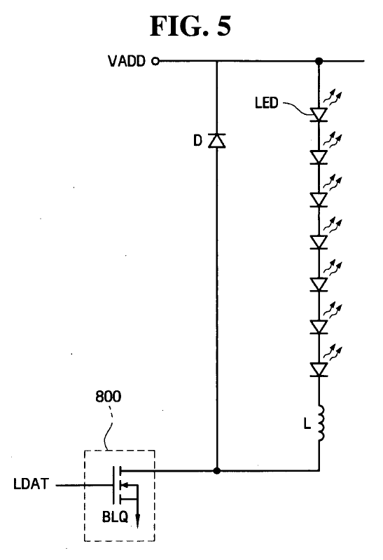

The backlight driver 800 adjusts luminance of back light supplied from a light-emitting block LB in response to a light data signal LDAT. The luminance of back light supplied from the light-emitting block LB may vary according to a duty ratio of the light data signal LDAT. The internal structure and operation of the backlight driver 800 will later be described in more detail with reference to FIG. 5.

The light-emitting block LB may include at least one light source and provides back light to the display panel 300. In one exemplary embodiment, the light-emitting block LB may include a light-emitting diode (“LED”), e.g., a point light source, as shown. However, alternative exemplary embodiments include configurations wherein the light source may be a line light source, or a surface light source. The luminance of back light supplied from the light-emitting block LB may be controlled by the backlight driver 800 connected to the light-emitting block LB.

FIG. 3 is a detailed block diagram of an exemplary embodiment of the image signal control unit 600_1 illustrated in FIG. 1. Referring to FIG. 3, the image signal control unit 600_1 includes a control signal generator 610, an image signal processor 620, and a representative value determiner 630.

The control signal generator 610 receives the external control signals Vsync, Hsync, Mclk, and DE and outputs the data control signal CONT1 and the gate control signal CONT2. In detail, exemplary embodiments of the control signal generator 610 may generate various signals, such as a vertical start signal STV for starting the operation of the gate driver 400 shown in FIG. 1, a gate clock CPV for determining an output time of the gate-on voltage Von, a gate output enable signal OE for determining a pulse width of the gate-on voltage Von, a horizontal synchronization start signal STH for starting the operation of the data driver 500, and an output instruction signal TP for instructing the output of an image data voltage.

The image signal processor 620 may receive first image signals R, G and B and output second image signals IDAT corresponding to the received first image signals R, G and B. The second image signals IDAT may be signals converted from the first image signals R, G and B for improving display quality, for example, the first image signal R, G and B may be converted by overdriving. Overdriving and other methods for improving display quality would be well-known to one of ordinary skill in the art, and a detailed explanation about their operation will not be given herein.

The representative value determiner 630 determines a representative image signal R_DB displayed on the display panel 300. For example, the representative value determiner 630 may receive the first image signals R, G, and B and determine the representative image signal R_DB. In one exemplary embodiment, the representative image signal R_DB may be an average luminance value of the first image signals R, G, and B. Thus, the representative image signal R_DB may indicate an average luminance value of the image displayed on the display panel 300.

FIG. 4 is a block diagram of the light data signal control unit 600_2 illustrated in FIG. 1. Referring to FIGS. 1 and 4, the present exemplary embodiment of a light data signal control unit 600_2 includes a luminance determiner 640, a luminance compensator 650, and a light data signal output portion 660.

The luminance determiner 640 receives the representative image signal R_DB, determines a luminance R_LB of back light corresponding to the representative image signal R_DB, and outputs the luminance R_LB of back light to the luminance compensator 650. In one exemplary embodiment, the luminance determiner 640 may determine the luminance R_LB of back light using, a look-up table (not shown). Alternative exemplary embodiments include configurations wherein the luminance determiner 640 determines luminance R_LB of back light using alternative methods, as would be apparent to one of ordinary skill in the art.

The luminance compensator 650 receives the native luminance R_LB and the back light luminance level IL, and supplies compensated luminance R′_LB to the light data signal output portion 660. The luminance compensator 650 provides the light data signal output portion 660 with the compensated luminance R′_LB, which is compensated according to the luminance of ambient light. Here, the back light luminance level IL may be a value obtained by measuring the luminance of ambient light. In detail, in one exemplary embodiment, if the luminance of ambient light is low, the back light luminance level IL is a small value, while if the luminance of ambient light is high, the back light luminance level IL is a large value.

The luminance of back light can be adjusted depending on the luminance of ambient light by compensating the luminance R_LB using the back light luminance level IL, which varies according to the luminance of ambient light, e.g., light coming from external to the display 10. That is to say, if the luminance of ambient light is low, the luminance of back light is reduced, and if the luminance of ambient light is high, the luminance of back light is increased. In such a manner, the display quality can be improved and power consumption can be reduced.

Alternatively, the luminance compensator 650 provides the light data signal output portion 660 with the compensated luminance R′_LB, which is compensated according to the measured luminance of back light, e.g., light coming from the light-emitting block LB. In this exemplary embodiment, the back light luminance level IL may correspond to the measured luminance of back light. In detail, in one exemplary embodiment, if the measured luminance of back light is smaller than a desired value, the back light luminance level IL may be a large value, while if the measured luminance of back light is greater than a desired value, the back light luminance level IL may be a small value.

For example, in an exemplary embodiment where a light-emitting device including the light-emitting unit LB deteriorates over time, the luminance of back light supplied from the light-emitting unit LB may be lower than a desired luminance value even though the same driving signals are applied thereto. In this case, compensation can be made to achieve a desired level of back light supplied from the light-emitting unit LB by increasing the back light luminance level IL and compensating for the luminance R_LB using the increased back light luminance level.

As described above, the measured luminance of back light is compared with a desired luminance level, and the luminance R_LB of back light is compensated using the adjusted back light luminance level IL, thereby controlling the luminance of back light to reach a desired level to improve display quality and reduce power consumption.

The light data signal output portion 660 outputs the light data signal LDAT according to the compensated luminance R′_LB provided from the luminance compensator 650. The light data signal LDAT corresponding to the compensated luminance R′_LB is supplied to the backlight driver 800, thereby adjusting the luminance of back light supplied from the light-emitting unit LB.

FIG. 5 is an equivalent circuit diagram illustrating exemplary embodiments of operations of the backlight driver 800 and the light-emitting block LB illustrated in FIG. 1. Referring to FIG. 5, the backlight driver 800, including a switching element BLQ, controls luminance of the light-emitting block LB in response to the light data signal LDAT.

The backlight driver 800 operates as follows. When the light data signal LDAT is activated to a high level, the switching element BLQ of the backlight driver 800 is turned on and a power supply voltage Vin is supplied to the light-emitting block LB. Accordingly, current flows through the light-emitting block LB and an inductor L. Here, the inductor L stores the energy derived from the current. When the light data signal LDAT is activated to a low level, the switching element BLQ is turned off, creating a closed circuit constituted by the light-emitting block LB, the inductor L, and a diode D, so that current flows therethrough. As the energy stored in the inductor L is discharged, the quantity of current is reduced. Since a time taken for the switching element BLQ to be turned on is adjusted according to the duty ratio of the light data signal LDAT, the luminance of the light-emitting block LB can be controlled.

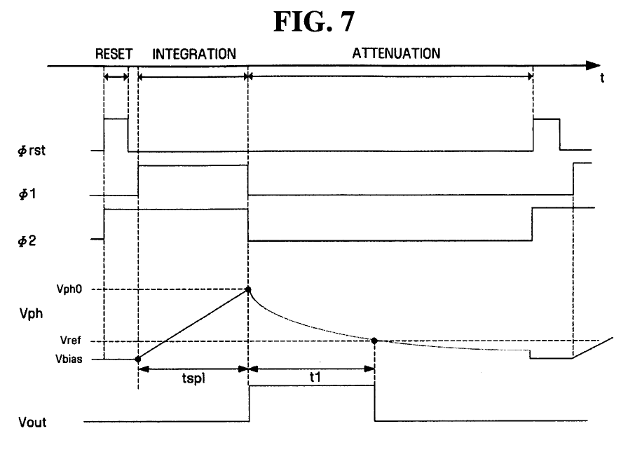

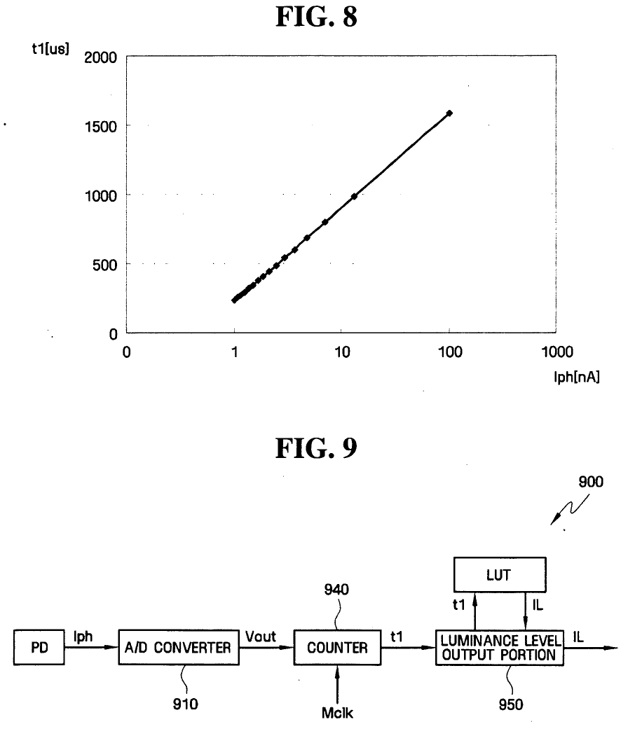

The light measuring unit 900 illustrated in FIG. 1 will be described in greater detail with reference to FIGS. 6 through 9. FIG. 6 is an equivalent circuit diagram of an A/D converter 910 included in an exemplary embodiment of a light measuring unit 900 illustrated in FIG. 1, FIG. 7 is a timing diagram illustrating signals for driving the exemplary embodiment of a circuit illustrated in FIG. 6, FIG. 8 is a graph illustrating a change in the length of “t1” illustrated in FIG. 7 depending on the magnitude of photocurrent “Iph” illustrated in FIG. 6, and FIG. 9 is a block diagram illustrating the exemplary embodiment of a light measuring unit 900 illustrated in FIG. 1. For brevity of explanation, a photoelectric conversion element PD is also illustrated in FIG. 6.

Referring to FIG. 6, the A/D converter 910 included in the light measuring unit 900 illustrated in FIG. 1 includes a photocurrent integrator 920, a discharger 930, a comparator “cpr”, and a reset switch. In FIG. 6, a first selection switch SEL1 may be closed, so that a first capacitor C1 may function as a feedback capacitor.

The photocurrent integrator 920 integrates photocurrent Iph and stores the integrated photocurrent in the feedback capacitor in the form of voltage. The photocurrent integrator 920 includes an operational amplifier “amp” having a first input node connected to the photoelectric conversion element PD through which the photocurrent Iph flows, and a second input node to which a bias voltage “Vbias” is applied; and a feedback capacitor connected between the first input node and the output node of the operational amplifier amp. In one exemplary embodiment, the photocurrent integrator 920 may be, for example, a photodiode, as illustrated in FIG. 6.

A voltage “Vph” output from the photocurrent integrator 920 is applied to a node of the discharger 930. The discharger 930 attenuates the voltage Vph output from the photocurrent integrator 920 in the form of an exponential function. As shown in FIG. 6, the discharger 930 may be a resistor-capacitor (“RC”) primary circuit constituted by a resistor RL and a capacitor CL. A bias voltage Vbias is applied to the other node of the discharger 930.

The comparator cpr receives a voltage “Vph” attenuated by the discharger 930 and a reference voltage “Vref”, compares the received voltages with each other, and outputs a comparison result. For example, the comparator cpr may output a signal in a high level for a time period in which the voltage Vph attenuated by the discharger 930 reaches the reference voltage Vref. That is to say, in one exemplary embodiment, the voltage “Vout” output from the comparator cpr may be a digital signal composed of a combination of a high level and a low level.

The reset switch is connected between the first input node and the output node of the operational amplifier amp. The reset switch is turned on in response to a reset signal Φ rst, and resets the voltage Vph output from the photocurrent integrator 920 to a bias voltage Vbias.

The operation of the A/D converter 910 illustrated in FIG. 6 will now be described with reference to FIGS. 6 and 7. First, in a reset period, when a reset signal Φ rst and a Φ2 signal are activated to high level, a node to which the voltage Vph output from the photocurrent integrator 920 is output is connected to the output port of the operational amplifier amp, and the voltage Vph output from the photocurrent integrator 920 is connected to an output node of the operational amplifier amp. In addition, a node to which the voltage Vph output from the photocurrent integrator 920 is output is disconnected from the first input node of the operational amplifier amp. Here, a voltage of the first input node is the same as that of the second input node to which the bias voltage Vbias is applied. Accordingly, the voltage Vph output from the photocurrent integrator 920 is reset to a value of the bias voltage Vbias.

Next, in an integration period, when Φ1 and Φ2 signals are activated to high levels, a feedback capacitor, e.g., a first capacitor C1, is charged with photocurrent Iph for a time period tsp1 corresponding to the high-level period, and the voltage Vph output from the photocurrent integrator 920 increases with a predetermined slope. If the voltage Vph output from the photocurrent integrator 920 reaches a value of Vph0 at a timing point at which the Φ1 and Φ2 signals go low, the value of Vph0 can be expressed as:

(Vph0−Vbias)*C1=Iph*tsp1 Equation (1):

Next, in an attenuation period, if Φ1 and Φ2 signals are maintained at low levels, the voltage Vph output from the photocurrent integrator 920 is attenuated with a time constant τ of the discharger 930. That is to say, the voltage Vph output from the photocurrent integrator 920 is attenuated with the time constant τ in the form of an exponential function, which can be expressed as τ=RL*CL.

Assuming that a timing point at which the voltage Vph output from the photocurrent integrator 920 reaches Vph0 is set to be t=0, Vph(t) at an arbitrary time t can be expressed as:

{Vph(t)−Vbias}=(Vph0−Vbias)*exp(−t/τ) Equation (2):

Assuming that t1 denotes a time taken for the voltage Vph output from the photocurrent integrator 920 to reach the reference voltage Vref by attenuation, the following equation can be produced from Equation (2):

(Vref−Vbias)=(Vph0−Vbias)*exp(−t1/τ) Equation (3):

In Equation (1), the equation (Vph0−Vbias)=(Iph*tsp1)/C1 is applied to Equation (3), producing Equation (4):

(Vref−Vbias)=(Iph*tsp1)/C1*exp(−t1/τ) Equation (4):

Taking the natural logs and rearranging for t1:

t1=τ[ln(Iph)−ln{(Vref−Vbias)*C1/tsp1}] Equation (5):

Converting the natural log of the right side of Equation (5) into a log having a base of 10:

t1=(τ/loge)*[log(Iph)−log{(Vref−Vbias)*C1/tsp1}] Equation (6):

In Equation (6), since τ, Vref, Vbias, C1, and tsp1 are all constants, Equation (6) can be rewritten as:

t1=A*log(Iph)+B Equation (7):

where A=τ/loge, B=−τ*ln{(Vref−Vbias)*Cf/tsp1}.

That is to say, the time t1 taken for the voltage attenuated by the discharger 930 to reach the reference voltage Vref is linearly proportional to the log value of photocurrent Iph.

FIG. 8 is a graphical representation of values resulting from simulation of a circuit illustrated in FIG. 6. In FIG. 8, a relationship between t1 and log (Iph) is illustrated, the relationship obtained by measuring t1 for photocurrent (Iph) values ranging between 1 nA and 100 nA. Referring to FIG. 8, a linear relation between t1 and log (Iph) is illustrated. As described above, according to an exemplary embodiment of the present invention, the A/D converter 910 in which a linear relation between t1 and log (Iph) is demonstrated can be simply implemented.

Referring to FIG. 9, the light measuring unit 900 illustrated in FIG. 1 includes the photoelectric conversion element PD, an A/D converter 910, a counter 940, and a luminance level output portion 950.

The A/D converter 910 receives the photocurrent Iph output from the photoelectric conversion element PD and outputs the output voltage Vout, as described with reference to FIGS. 6 through 8.

The counter 940 receives the output voltage Vout from the A/D converter 910 and outputs the output voltage Vout at a high level for a time period t1 as illustrated in FIG. 7. Here, the counter 940 may output a length of the time period t1 as a digital value using the main clock signal Mclk illustrated in FIG. 1.

The luminance level output portion 950 receives the length of the time period t1 from the counter 940 and outputs a back light luminance level IL corresponding thereto. Here, in one exemplary embodiment, the corresponding relationship between the time period t1 and the back light luminance level IL may be stored in a lookup table LUT. The luminance level output portion 950 may output the back light luminance level IL corresponding to the time period t1 using the LUT.

As described above with reference to FIG. 4, the photocurrent Iph illustrated in FIG. 9 may be generated by ambient light that is supplied externally to the display 10. In this case, if the time period t1 is long, the luminance of ambient light is low, while the time period t1 is short, the luminance of ambient light is high. In the former case, the luminance level output portion 950 outputs a small back light luminance level IL. In the latter case, the luminance level output portion 950 outputs a large back light luminance level IL.

In such a manner, the luminance of back light can be adjusted using the back light luminance level IL varying depending on the luminance of ambient light. That is to say, if the ambient light is low, the luminance of back light may be reduced, while if the ambient light is high, the luminance of back light may be increased.

Alternatively, as described above with reference to FIG. 4, the photocurrent Iph illustrated in FIG. 9 may be generated by back light. In this case, a magnitude of the photocurrent Iph depending on the actual luminance of back light can be obtained from the length of the time period t1. The luminance level output portion 950 may compare the magnitude of the photocurrent Iph with a magnitude of the photocurrent Iph which would result from a desired back light luminance. As a comparison result, if measured luminance of back light is smaller than a desired value, the luminance level output portion 950 may output a back light luminance level IL greater than the measured back light luminance. In this way, the luminance of back light can be controlled until it reaches a desired luminance value by comparing the measured back light luminance with a desired back light luminance value.

Meanwhile, in one exemplary embodiment, the A/D converter 910, the counter 940 and the luminance level output portion 950 of the light measuring unit 900 may be mounted on the display panel 300, as illustrated in FIG. 1. Alternative exemplary embodiments include configurations wherein, the A/D converter 910, the counter 940 and the luminance level output portion 950 of the light measuring unit 900 may be mounted on the gate driver 400 or the data driver 500.

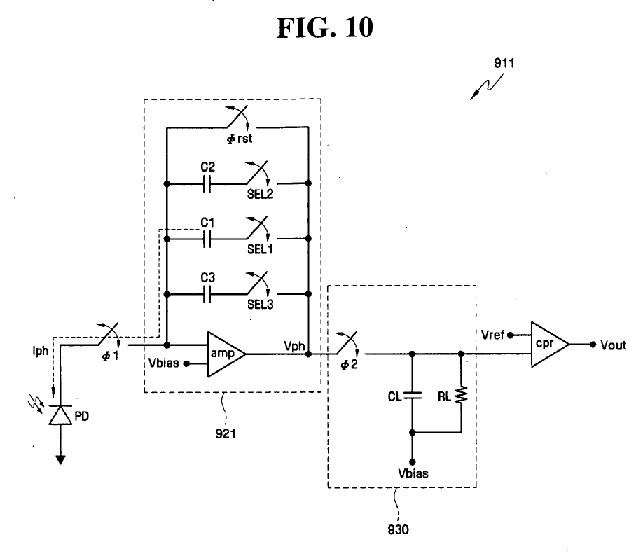

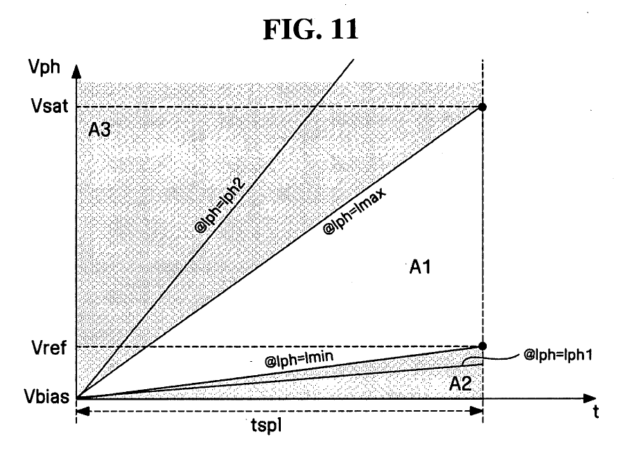

Another exemplary embodiment of a display device and a driving method of the same according to the present invention will be described with reference to FIGS. 10 and 11. FIG. 10 is an equivalent circuit diagram of an exemplary embodiment of an A/D converter 911 included in the light measuring unit 900 illustrated in FIG. 1 in another exemplary embodiment of a display device according to the present invention, and FIG. 11 is a graph illustrating conditions for selecting one among first to third feedback capacitors C1, C2, and C3 in the circuit illustrated in FIG. 10. Like elements are denoted by like numbers, and their repetitive descriptions will be omitted for brevity of explanation.

Referring to FIG. 10, in the present exemplary embodiment of a display device, the A/D converter 911 included in the light measuring unit 900 illustrated in FIG. 1 can vary the capacitance of a feedback capacitor according to the magnitude of photocurrent Iph.

The operation of the A/D converter 911 will now be described in more detail. A photocurrent integrator 921 may include a first capacitor C1, a second capacitor C2 having capacitance smaller than that of the first capacitor C1, and a third capacitor C3 having capacitance larger than that of the first capacitor C1. In one exemplary embodiment, the capacitance of the second capacitor C2 may be ( 1/10)ⁿ times that of the first capacitor C1, and the capacitance of the third capacitor C3 may be 10 n times that of the first capacitor C1, wherein “n” is a positive real number.

In addition, the photocurrent integrator 921 may include a first selection switch SEL1 limiting current flow toward the first capacitor C1, a second selection switch SEL2 limiting current flow toward the second capacitor C2, and a third selection switch SEL3 limiting current flow toward the third capacitor C3.

The operation of the photocurrent integrator 921 will now be described in more detail. Depending on the magnitude of photocurrent Iph, one among the first capacitor C1, the second capacitor C2, and the third capacitor C3 may function as a feedback capacitor.

In detail, when the first selection switch SEL1 is closed so that the first capacitor C1 functions as a feedback capacitor, if t1, e.g., a time taken for an attenuated voltage to reach a reference voltage, is shorter than a predetermined time, the first selection switch SEL1 is opened and the second selection switch SEL2 may be closed. Accordingly, the second capacitor C2 may then function as a feedback capacitor.

Alternatively, when the first selection switch SEL1 is closed so that the first capacitor C1 functions as a feedback capacitor, if the photocurrent Iph value is greater than a saturation value of the operational amplifier amp, the first selection switch SEL1 may be opened and the third switch SEL3 may also be closed. Accordingly, the third capacitor C3 may function as a feedback capacitor.

Conditions for selecting one among first to third feedback capacitors C1, C2, and C3 in the circuit illustrated in FIG. 10 will now be described with reference to FIG. 11. For example, assumptions will be made that the capacitance of the second capacitor C2 is 1/10 times that of the first capacitor C1, and that the capacitance of the third capacitor C3 is 10 times that of the first capacitor C1.

Referring to FIG. 11, if the photocurrent Iph value Vph0 is extremely low, e.g., low enough to be smaller than the reference voltage Vref, a time period t1 is always 0. Conversely, if the photocurrent Iph value Vph0 is exceedingly large, the output voltage of the operational amplifier amp is saturated to a saturation voltage Vsat. Then, the time period t1 is fixed to a predetermined value at which Vph0 is attenuated at the saturation voltage Vsat. In this case, a length of the time period t1 cannot meaningfully reflect information about the photocurrent Iph value. A range of photocurrent Iph values, e.g., an A1 area, where such an event does not occur, is referred to as an input dynamic range, and can be generally represented as: 20*log (Imax/Imin) dB.

Referring to FIGS. 10 and 11, if the photocurrent Iph value is Iph1, which is smaller than Imin, e.g., the A2 area, the first selection switch SEL1 is opened and the second selection switch SEL2 is closed to reduce the value of the feedback capacitor to 1/10 times. Then, as confirmed from Equation (1), since the (Vph0−Vbias) value is increased by 10 times, it is possible to detect a photocurrent Iph value of 10 times smaller than ph1, thereby increasing the input dynamic range. As indicated in Equation (7), t1 obtained from the 10-fold increased (Vph0−Vbias) value is larger than an actual value of t1 by an amount equal to A. Accordingly, the actual t1 value can be obtained by subtracting A from t1. In the same manner, the input dynamic range can be further increased by decreasing the capacitance of the feedback capacitor to 1/10 times, 1/100 times, and so on.

Conversely, referring to FIGS. 10 and 11, if the photocurrent Iph value is Iph2, which is greater than Imax, e.g., in the A3 area, the first selection switch SEL1 is opened and the third selection switch SEL3 is closed to increase the value of the feedback capacitor to 10 times. Then, as confirmed from Equation (1), since the (Vph0−Vbias) value is increased by 10 times, it is possible to detect a photocurrent Iph value of 10 times larger than ph1, thereby increasing the input dynamic range. As indicated in Equation (7), t1 obtained from the 10-fold increased (Vph0−Vbias) value is smaller than the actual value of t1 by a quantity equal to A. Accordingly, the actual value of t1 can be obtained by adding A to t1. In the same manner, the input dynamic range can be further increased by decreasing the capacitance of the feedback capacitor to 10 times, 100 times, and so on.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. An analog-to-digital converter comprising:
a photocurrent integrator which integrates photocurrent and stores the integrated photocurrent in a feedback capacitor in the form of voltage; and
a discharger which attenuates the voltage out from the photocurrent integrator in the form of an exponential function.

2. The analog-to-digital converter of claim 1, further comprising a comparator which compares a voltage attenuated by the discharger with a reference voltage, and a time taken for the voltage attenuated by the discharger to reach the reference voltage is linearly proportional to the log value of the photocurrent.

3. The analog-to-digital converter of claim 1, further comprising a comparator which compares the voltage attenuated by the discharger with the reference voltage, and which outputs a signal in a high level for a time period in which the voltage attenuated by the discharger is equal to or greater than the reference voltage.

4. The analog-to-digital converter of claim 1, wherein the photocurrent integrator comprises:
an operational amplifier having a first input node connected to a photoelectric conversion element through which the photocurrent flows, and a second input node to which a bias voltage is applied,
wherein the feedback capacitor is connected between the first input node and the output node of the operational amplifier.

5. The analog-to-digital converter of claim 1, wherein the discharger is a resistor-capacitor primary circuit.

6. The analog-to-digital converter of claim 1, wherein the photocurrent integrator comprises:
an operational amplifier having a first input node connected to a photoelectric conversion element through which the photocurrent flows, and a second input node to which a bias voltage is applied; and
a reset switch connected between the first input node and the output node of the operational amplifier, and which resets the voltage output from the photocurrent integrator to the bias voltage when closed.

7. The analog-to-digital converter of claim 1, wherein the photocurrent integrator includes:
a first capacitor;
a second capacitor having a capacitance smaller than that of the first capacitor; and
a third capacitor having a capacitance larger than that of the first capacitor,
wherein one among the first capacitor, the second capacitor, and the third capacitor functions as the feedback capacitor, depending upon the magnitude of the photocurrent.

8. The analog-to-digital converter of claim 1, wherein the photocurrent integrator includes:
a first capacitor;
a second capacitor having capacitance smaller than that of the first capacitor;
a first selection switch which limits current flow toward the first capacitor;
a second selection switch which limits current flow toward the second capacitor,
wherein the analog-to-digital converter further includes a comparator which compares a voltage attenuated by the discharger with a reference voltage, and
wherein when a time taken for the voltage attenuated by the discharger to reach the reference voltage is shorter than a predetermined time, the first selection switch is opened and the second selection switch is closed, so that the second capacitor functions as the feedback capacitor.

9. The analog-to-digital converter of claim 8, wherein the capacitance of the second capacitor is ( 1/10)ⁿ times that of the first capacitor, wherein n is a positive real number.

10. The analog-to-digital converter of claim 1, wherein the photocurrent integrator includes:
a first capacitor;
a third capacitor having capacitance larger than that of the first capacitor;
a first selection switch limiting current flow toward the first capacitor;
a third selection switch limiting current flow toward the third capacitor;
an operational amplifier having a first input node connected to a photoelectric conversion element and receiving a photocurrent therefrom, and a second input node to which a bias voltage is applied,
wherein the photocurrent value is greater than a saturation value of the operational amplifier, the first selection switch is opened and the third switch is closed, so that the third capacitor functions as the feedback capacitor.

11. The analog-to-digital converter of claim 10, wherein the capacitance of the third capacitor is 10ⁿ times that of the first capacitor, wherein n is a positive real number.

12. A display device comprising:
an analog-to-digital converter including:
a photocurrent integrator which integrates photocurrent and stores the integrated photocurrent in a feedback capacitor in the form of voltage;
a discharger which attenuates the voltage out from the photocurrent integrator in the form of an exponential function; and
a comparator which compares the voltage attenuated by the discharger with a reference voltage;
a backlight unit which adjusts luminance of back light according to a time period wherein the attenuated voltage is greater than or equal to the reference voltage, and which outputs the same; and
a display panel which receives the back light.

13. The display device of claim 12, wherein the photocurrent is generated by ambient light which is supplied externally to the display, and when the time period is long, the luminance of back light is reduced, while when the time period is short, the luminance of back light is increased.

14. The display device of claim 12, wherein the photocurrent is generated by back light, the backlight unit supplies the back light in response to a light data signal, and the light data signal is adjusted according to a result of comparing the photocurrent with a reference current.

15. The display device of claim 12, wherein the analog-to-digital converter is mounted on one of the display panel, a gate driving chip, and a data driving chip.

16. A driving method of a display device comprising:
integrating photocurrent and storing the integrated photocurrent in a feedback capacitor in the form of voltage;
attenuating the voltage out from the photocurrent integrator in the form of an exponential function; and
adjusting luminance of back light according to a time period wherein the attenuated voltage is equal to or greater than a reference voltage, and outputting the same.

17. The driving method of claim 16, wherein the time taken for the voltage attenuated by the discharger to reach the reference voltage is linearly proportional to the log value of the photocurrent.

18. The driving method of claim 16, further comprising resetting the voltage output from the photocurrent integrator before the integrating of the photocurrent.

19. The driving method of claim 16, wherein the storing of the integrated photocurrent comprises storing the integrated photocurrent by varying the capacitance of the feedback capacitor according to a magnitude of the photocurrent.
